(19) United States
(12) Patent Application Publication
(10) Pub. No.: US 2009/0109595 A1
(43) Pub. Date: Apr. 30, 2009

(54) METHOD AND SYSTEM FOR PERFORMING ELECTROSTATIC CHUCK CLAMPING IN TRACK LITHOGRAPHY TOOLS

(75) Inventors: Harald Herchen, Los Altos, CA (US); Kim Vellore, San Jose, CA (US); Brian C. Lue, Mountain View, CA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Sokudo Co., Ltd., Shimogyo-ku (JP)

(21) Appl. No.: 11/933,152

(22) Filed: Oct. 31, 2007

(51) Int. Cl. H01L 21/683

(52) U.S. Cl. 361/234

(57) ABSTRACT

A method of clamping/declamping a semiconductor wafer on an electrostatic chuck in ambient air includes disposing the semiconductor wafer at a predetermined distance above a dielectric surface of the electrostatic chuck having one or more electrodes and applying a first voltage greater than a predetermined threshold to the one or more electrodes of the electrostatic chuck for a first time period. The method includes reducing the first voltage to a second voltage substantially equal to a self bias potential of the semiconductor wafer after the first time period. The method includes maintaining the second voltage for a second time period and adjusting the second voltage to a third voltage characterized by a polarity opposite to that of the first voltage and a magnitude smaller than the predetermined threshold. The method includes reducing the third voltage to a fourth voltage substantially equal to the second voltage after a third time period.

### BACKGROUND OF THE INVENTION

The present invention relates generally to the field of substrate processing equipment. More particularly, the present invention relates to a method and apparatus for performing electrostatic chucking of a semiconductor substrate wafer. Merely by way of example, the method and apparatus of the present invention are applied to clamp and declamp a semiconductor wafer on an electrostatic chuck for ambient thermal processing in a track lithography tool. The method and apparatus can be applied to other processing devices for semiconductor processing equipments utilized in other processing chambers.

Modem integrated circuits contain millions of individual elements that are formed by patterning the materials, such as silicon, metal and dielectric layers, that make up the integrated circuit to sizes that are small fractions of a micrometer. The technique used throughout the industry for forming such patterns is photolithography. A typical photolithography process sequence generally includes depositing one or more uniform photoresist (resist) layers on the surface of a substrate, drying and curing the deposited layers, patterning the substrate by exposing the photoresist layer to radiation that is suitable for modifying the exposed layer and then developing the patterned photoresist layer.

It is common in the semiconductor industry for many of the steps associated with the photolithography process to be performed in a multi-chamber processing system (e.g., a cluster tool) that has the capability to sequentially process semiconductor wafers in a controlled manner. One example of a cluster tool that is used to deposit (i.e., coat) and develop a photoresist material is commonly referred to as a track lithography tool.

Track lithography tools typically include a mainframe that houses multiple chambers (which are sometimes referred to herein as stations) dedicated to performing the various tasks associated with pre- and post-lithography processing. There are typically both wet and dry processing chambers within track lithography tools. Wet chambers include coat and/or develop bowls, while dry chambers include thermal control units that house bake and/or chill plates for supporting and retaining semiconductor wafers or other work-pieces in a stationary position during thermal processing. In order to secure the semiconductor wafers on the plates, the plates are generally configured as a type of chuck using either electrostatic force or vacuum. However, one potential problem is that if a substrate wafer is loaded directly onto the upper surface of a conventional electrostatic chuck during substrate processing, the chuck surface can abrade the material present on the backside of the substrate wafer, resulting in the introduction of particulate contaminants to the process environment. The particulate contaminants can adhere to the backside of another substrate wafer and be carried to other process environment or cause defects in the circuitry fabricated upon the substrate wafer. As the semiconductor device geometry has become smaller with each generation of ICs, these particulate contaminants can cause a loss in yield as well as degradation of device characteristics and reliability.

One method of reducing the number of particles generated on the backside of the substrate wafer is to reduce the contact area between the substrate wafer and the surface of the electrostatic chuck. This can be accomplished by, for example, using an array of proximity pins or support members that space the substrate at a predetermined distance from the surface of the electrostatic chuck. However, unlike a conventional electrostatic chuck usually used in vacuum systems, two major differences exist when trying to implement an electrostatic chuck for track lithography tool applications: both the ambient gas pressure and the gap between the substrate wafer and the surface of an electrostatic chuck with proximity pins are much higher than for conventional electrostatic chucks in vacuum applications. Because of the proximity pins, the gap is in a range from 50 μm to 100 μm, which is at least one order magnitude larger than a conventional “direct-contact” type chuck. Additionally, the pressure during thermal processing in track lithography tools may be as high as one atmosphere and a certain humidity level also exists in the process chamber. Under such ambient conditions with humidity, the chucking force based on traditional techniques have been found to be significantly reduced, resulting in unsecured clamping of the substrate wafer.

Thus, there is a need in the art for improved methods and apparatuses for performing electrostatic chucking of semiconductor wafers during thermal processing operations in ambient air within the track lithography tool.

### SUMMARY OF THE INVENTION

According to embodiments of the present invention, techniques related to the field of substrate processing equipment are provided. More particularly, the present invention relates to a method and apparatus for performing electrostatic chucking of a semiconductor substrate wafer. Merely by way of example, the method and apparatus of the present invention are applied to clamp and declamp a semiconductor wafer on an electrostatic chuck for ambient thermal processing in a track lithography tool. The method and apparatus can be applied to other processing devices for semiconductor processing equipments utilized in other processing chambers.

In a specific embodiment, the invention provides a method of clamping and declamping a semiconductor wafer on an electrostatic chuck in ambient air. The method includes disposing a semiconductor wafer at a predetermined distance above a dielectric surface of the electrostatic chuck having one or more electrodes and applying a first voltage to the one or more electrodes of the electrostatic chuck for a first time period. The first voltage is greater than a predetermined threshold. The method further includes reducing the first voltage to a second voltage after the first time period. The second voltage is substantially equal to a self bias potential of the semiconductor wafer. Additionally, the method includes maintaining the second voltage for a second time period and adjusting the second voltage to a third voltage. The third voltage is characterized by a polarity opposite to that of the first voltage and a magnitude smaller than the predetermined threshold. Moreover, the method includes reducing the third voltage to a fourth voltage after a third time period. The fourth voltage is substantially equal to the second voltage.

In certain specific embodiments, the method provided by the invention further includes disposing a second semiconductor wafer on the electrostatic chuck after replacing the first semiconductor wafer. Furthermore, the method includes applying a fifth voltage to the one or more electrodes for chucking the second semiconductor wafer. The fifth voltage is characterized by a polarity opposite to the first voltage and a magnitude greater than the predetermined threshold.

In another specific embodiment, the invention provides a method of performing electrostatic chucking of a semiconductor wafer in ambient air. The method includes providing an e-chuck in a chamber with ambient air. The e-chuck includes one or more electrodes and a dielectric plate with a plurality of proximity pins. The method further includes applying a first voltage greater than a predetermined threshold to the one or more electrodes for a first time period and disposing a semiconductor wafer on the dielectric plate such that a separation between the semiconductor wafer and the dielectric plate is reduced until at a time when the semiconductor wafer is in contact with the plurality of proximity pins. The method further includes reducing the first voltage to a second voltage after the first time period. The second voltage is substantially equal to a self-bias potential of the semiconductor wafer. Additionally, the method includes maintaining the second voltage for a second time period and changing the second voltage to a third voltage. The third voltage is characterized by a first polarity opposite to that of the first voltage and a first magnitude greater than the predetermined voltage threshold. Moreover, the method includes switching the third voltage after a third time period to a fourth voltage. The fourth voltage is characterized by a second polarity opposite to that of the third voltage and a second magnitude smaller than the predetermined voltage threshold. Furthermore, the method includes adjusting the fourth voltage after a fourth time period to a fifth voltage. The fifth voltage is substantially equal to the second voltage.

In an alternative embodiment, the invention provides a track lithography tool that includes a process chamber and an electrostatic chuck disposed in the process chamber. The electrostatic chuck includes a dielectric plate and one or more electrodes. The track lithography tool also includes one or more capacitance sensors disposed on the dielectric plate and a transfer robot configured to position a conductive wafer at a predetermined distance above the dielectric plate. The track lithography tool further includes a power supply configured to apply a voltage to the one or more electrodes. The power supply includes a computer-readable medium storing a plurality of instructions for controlling a data processor to adjust the voltage. The plurality of instructions additionally includes instructions that cause the data processor to adjust the voltage to a first voltage for a first time period. The first voltage is greater than a predetermined threshold. The plurality of instructions includes instructions that cause the data processor to reduce the first voltage to a second voltage after the first time period. The second voltage is substantially equal to a self bias potential of the semiconductor wafer. The plurality of instructions also includes instructions that cause the data processor to maintain the voltage at the second voltage for a second time period and instructions that cause the data processor to adjust the second voltage to a third voltage characterized by a polarity opposite to that of the first voltage and a magnitude smaller than the predetermined threshold. The plurality of instructions further includes instructions that cause the data processor to reduce the third voltage to a fourth voltage after a third time period. The fourth voltage is substantially equal to the second voltage.

In yet another alternative embodiment, a track lithography tool is provided to include a process chamber and a bipolar electrostatic chuck disposed in the process chamber. The bipolar electrostatic chuck includes two electrodes and a dielectric plate with a plurality of proximity pins. The track lithography tool further includes one or more capacitance sensors disposed on the dielectric plate and a transfer robot configured to dispose a conductive wafer on the dielectric plate such that a separation between the conductive wafer and the dielectric plate is reduced until the conductive wafer is in contact with the plurality of proximity pins. Additionally, the track lithography tool includes a power supply configured to apply a voltage to each of the two electrodes and a controller coupled to the power supply. The controller includes a computer-readable medium storing a plurality of instructions for controlling a data processor to adjust the voltage. The plurality of instructions includes instructions that cause the data processor to adjust the voltage to a first voltage greater than a predetermined threshold for a first time period. The plurality of instructions includes instructions that cause the data processor to reduce the first voltage to a second voltage after the first time period. The second voltage is substantially equal to a self-bias potential of the semiconductor wafer. Additionally, the plurality of instructions includes instructions that cause the data processor to maintain the second voltage for a second time period and instructions that cause the data processor to change the second voltage to a third voltage characterized by a first polarity opposite to that of the first voltage and a first magnitude greater than the predetermined threshold. The plurality of instructions further includes instructions that cause the data processor to switch the third voltage after a third time period to a fourth voltage characterized by a second polarity opposite to that of the third voltage and a second magnitude smaller than the predetermined threshold. Moreover, the plurality of instructions includes instructions that cause the data processor to adjust the fourth voltage after a fourth time period to a fifth voltage. The fifth voltage is substantially equal to the second voltage.

Depending upon the embodiment, many benefits can be achieved, particularly for achieve enhanced chucking pressure for clamping semiconductor wafer on a bipolar electrostatic chuck in ambient environment where the pressure can be as high as one atmosphere with certain humidity and the wafer-to-chuck gap distance is unusually one or two orders of magnitude larger than conventional chucks. These and other benefits may be described throughout the present specification and more particularly below.

### BRIEF DESCRIPTION OF THE DRAWINGS

FIGS. 1A-1C schematically show exemplary electrostatic chucking sequences used for wafer handling in a track lithography tool according to an embodiment of the present invention;

FIG. 2 shows a typical plot of an air breakdown voltage as a function of pressure-gap distance product and shows several conventional wafer chucking operating points and two desired wafer chucking operating points according to certain embodiments of the present invention;

FIG. 3 shows an exemplary chucking and dechucking sequence according to an embodiment of the present invention;

FIG. 4 is an exemplary flowchart showing a method for clamping and declamping a semiconductor wafer on an electrostatic chuck in ambient air according to an embodiment of the present invention;

FIG. 5A shows an exemplary chucking and dechucking sequence according to an alternative embodiment of the present invention;

FIG. 5B shows another exemplary chucking and dechucking sequence according to another embodiment of the present invention;

FIG. 6 is an exemplary flowchart showing a method for clamping and declamping a semiconductor wafer on an electrostatic chuck according to an alternative embodiment of the present invention; and

FIG. 7 is a simplified plan view of a track lithography tool according to an embodiment of the present invention.

### DETAILED DESCRIPTION OF SPECIFIC EMBODIMENTS

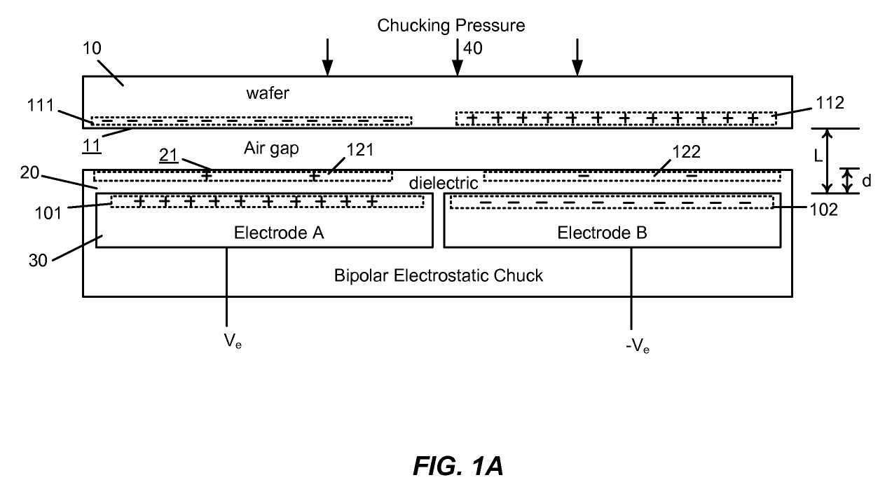

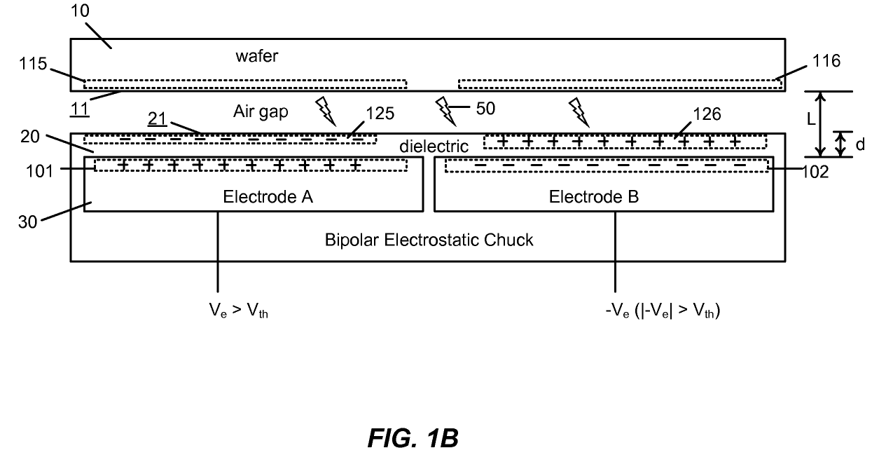

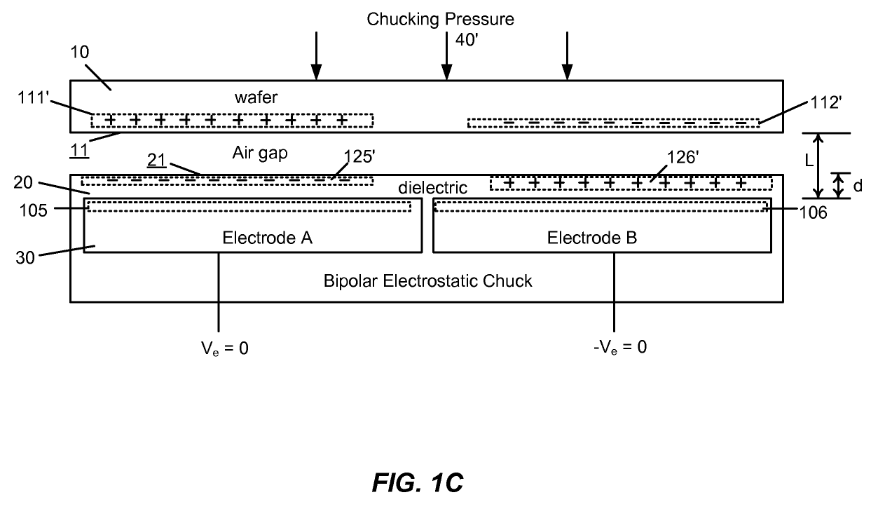

FIGS. 1A-1C schematically show exemplary electrostatic chucking sequences used for wafer handling in a track lithography tool according to an embodiment of the present invention. As shown in FIG. 1A, a bipolar electrostatic chuck 20 is provided. The bipolar electrostatic chuck 20 includes a dielectric plate and two electrodes 30, e.g., Electrode A and Electrode B, being embedded therein. A semiconductor wafer 10 can be disposed at a predetermined distance above an upper surface 21 of the dielectric plate of the bipolar electrostatic chuck 20. In FIG. 1A, d is denoted as a thickness of the dielectric plate, i.e., a distance between the upper surface 21 of the dielectric plate and each of the two electrodes 30. L is denoted as a distance between a lower surface 11 of the semiconductor wafer 10 and each of the two electrodes 30. Thus, the difference (L−d) is the predetermined distance at which the wafer 10 is disposed above the surface 21, representing a gap-distance between the wafer and the dielectric plate. In one example, air at ambient pressure is present in the gap for an electrostatic chuck installed in a track lithography tool. In another example, air at ambient pressure may be just part of a particular processing environment for various wafer treatments. For example, the wafer may be thermally treated in ambient air with a pressure of about 1 atm and a controlled humidity (e.g., 42% RH).

The two electrodes are made of electrical conductors and configured to receive voltages adjustable both in polarity and a wide range of magnitudes from an external power supply (not shown). For example. a voltage Vₑ is applied to each of the two electrodes 30. For the bipolar electrostatic chuck, the voltage on Electrode A has an opposite polarity to the voltage on Electrode B. For symmetric electrodes, the voltage magnitude on Electrode A can be the same as the voltage magnitude on Electrode B. The semiconductor wafer 10 usually can be grounded with a potential of V_{w}˜0. In certain embodiment, if a monopolar electrostatic chuck is used, an additional plasma environment may be used in the vicinity between the wafer and dielectric plate for assisting electrostatic chucking. The plasma may induce a non-zero self bias potential V_{w}≠0 for the wafer. The potential difference between the electrode and wafer Vₑ-V_{w} would induce a build-up of static charge on the surface of wafer and electrodes. For example, charges 111 form on one region of the lower surface 11 of the wafer 10 and correspondingly charges 101 with opposite sign form on the opposing surface of the Electrode A. Similarly, charges 102 form on another region of the lower surface 11 of the wafer 10 and correspondingly charges 102 with opposite sign form on the opposing surface of the Electrode B. These static charges with opposite signs create an electric field across the distance L (including the gap-distance (L−d) and the dielectric plate thickness (d)). Because of the opposite polarity of the applied voltages on the two electrodes, the sign of charges 101 is opposite to charges 102, and the sign of charges 111 is opposite to charges 112.

In one embodiment, the dielectric plate of the bipolar electrostatic chuck 20 is made of materials characterized by high dielectric constant and high resistivity. However, even with electric insulators, certain vertical charge motion may still occur when the voltage Vₑ is applied, resulting in charges 121 and 122 to some extent on the corresponding regions of the upper surface 21 of the dielectric plate. These charges 121 and 122 (having an opposite sign versus 121) result in a surface potential Vₛ for the surface 21. Theoretically all the charges on the surface 11, surface 21, and surfaces of Electrode A and Electrode B are static induced so that following relationship holds,

σₑ+σₛ+σ_{w}=0 (Eq. 1)

where σₑ denotes the charges on either Electrode A or Electrode B (for example charges 101 or 102), σₛ the charges on the surface of dielectric plate (for example charges 121 or 122), and σ_{w} the charges on the wafer surface (for example, charges 111 or 112). Using the definition of voltage drop,

V(\vec{r})=−∫_{∞}^{r}\vec{E}·\vec{ds} (Eq. 2)

we obtain the voltage potential at the surface of the dielectric plate

$${V}_{s} = {V}_{e} - \frac{1}{2 {κɛ}_{0}} ( {σ}_{e} - {σ}_{s} - {σ}_{w} ) d \qquad ( Eq . 3 )$$

and the voltage potential at the wafer surface

$${V}_{w} = {V}_{e} - \frac{1}{2 {κɛ}_{0}} ( {σ}_{e} - {σ}_{s} - {σ}_{w} ) d - \frac{1}{2 {ɛ}_{0}} ( {σ}_{e} + {σ}_{s} - {σ}_{w} ) ( L - d ) \qquad ( Eq . 4 )$$

where κ is the dielectric constant of the dielectric plate relative to that of air. After some manipulation, the charges induced on the lower surface of the wafer can be represented as

$${σ}_{w} = \frac{{κɛ}_{0} ( {V}_{w} - {V}_{e} ) - {σ}_{s} d}{d + κ ( L - d )} . \qquad ( Eq . 5 )$$

The electric field corresponding to the induced charges on the wafer surface is then

$${E}_{w} = \frac{1}{{ɛ}_{0}} ( \frac{{κɛ}_{0} ( {V}_{e} - {V}_{w} ) + {σ}_{s} d}{d + κ ( L - d )} ) . \qquad ( Eq . 6 )$$

Subsequently, the electrostatic chucking pressure associated with the electric field and charges is

$$P = - \frac{1}{2 {ɛ}_{0}} {( \frac{{κɛ}_{0} ( {V}_{e} - {V}_{w} ) + {σ}_{s} d}{d + κ ( L - d )} )}^{2} , \qquad ( Eq . 7 )$$

with the negative sign simply meaning that the pressure P is in the opposite direction to the electric field direction. As shown in FIG. 1A, this pressure P is denoted as a chucking pressure 40. According to above expression of the chuck pressure (Eq. 7), as the gap-distance (L−d) or the gap between the wafer and the dielectric plate becomes larger the chucking force will be substantially reduced. For example, if κ˜10 (for alumina), with the gap-distance (L−d) being only 1/10 of the dielectric plate thickness (d), the chucking force will become smaller by a factor of 4.

In another embodiment of the application of electrostatic wafer chucking in a track lithography tool, the semiconductor wafer is eventually supported by, at least partially, a plurality of proximity pins (not shown) on the dielectric plate. Each of the plurality of proximity pins can be made from a sapphire ball (or other material) being partially embedded in a slot or other orifice on the surface of the dielectric plate and partially protrudes with a certain height. In a specific embodiment, as the wafer is supported by the plurality of proximity pins, most area of the lower surface of the wafer is separated from the surface of the dielectric plate by a distance. In fact the distance is the gap-distance (L−d) defined in FIG. 1A. As the semiconductor wafer is disposed in this way, the gap-distance (L−d) is substantially associated with the heights of the plurality of proximity pins, which may vary for different wafer positions due to wafer warpage and for different proximity pins due to their height variations. For example, the heights of the proximity pins can be in a range of from below 50 microns to 100 microns or above from one chuck to another. For a particular electrostatic chuck the height variation of the proximity pins may be in a range of a few tenth of microns or less. In another example, the wafer warpage for a 300 mm wafer may be 250 μm at room temperature and may become as large as 900 μm during thermal processing absent any force to keep the wafer flat during such processing.

As seen above, the gap-distance (L−d) for a wafer to be held on an electrostatic chuck in track lithography tool is about two orders of magnitude larger than conventional wafer-to-chuck gap. If a conventional chucking voltage is applied, the resulted chucking force may be too small to properly hold the wafer. On the other hand, unlike the conventional electrostatic chuck operated in vacuum, the absolute pressure in the gap or the vicinity of the wafer 10 and surface 21 can be as high as 1 atm of ambient air in a thermal processing chamber of track lithography tools. The chucking forces are found to be significantly reduced at ambient conditions as compared to the vacuum case, as pointed out by G. Kalkowski in a published article (Microelectronic Engineering, Vol 61-62, (2002), pp 357-361). However, embodiments of the present invention provide novel methods and apparatus to overcome the problem with reduced chucking forces for large wafer-to-chuck gap distance and high pressure. More details about the methods and apparatus for chucking a semiconductor wafer on an electrostatic chuck with a large gap in ambient air can be found through this specification and in particular below.

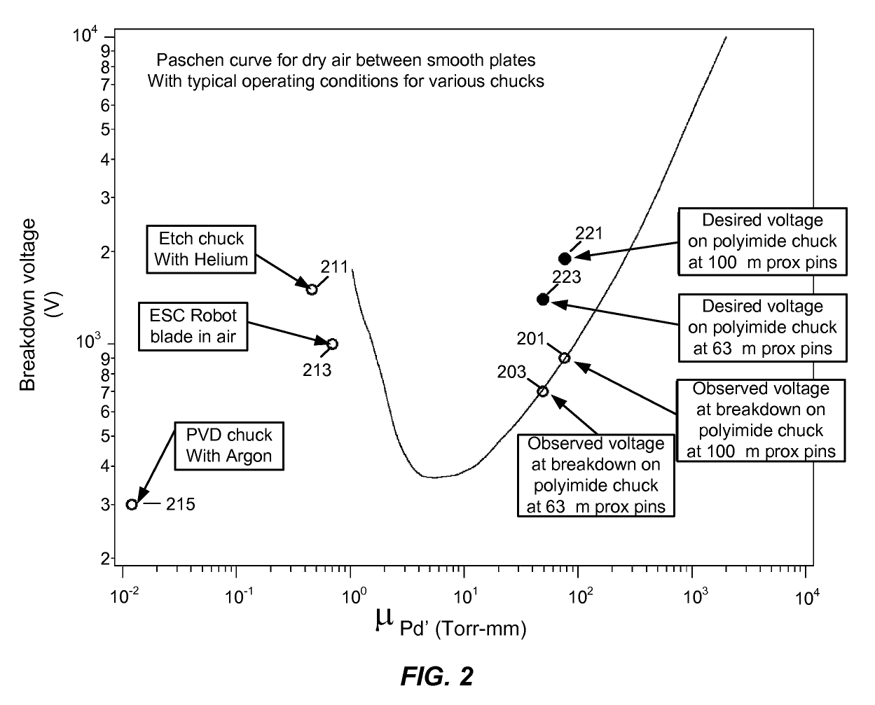

Because a high pressure exists in the air gap between the wafer and electrostatic chuck, as the voltage applied to the electrodes become higher (with an intention to induce more static charges), it is possible that an electric breakdown of the air between the lower surface 11 of the semiconductor wafer 10 and the upper surface 21 of the dielectric plate will occur. The electric breakdown simply turns insulating air into a conductive media to have a steady state charge transfer across the air gap. FIG. 2 shows a typical plot of the electric breakdown voltage V as a function of pressure-gap distance product Pd′. Here P represents a pressure within the gap and d′ represents a gap-distance. For example, the gap distance d′=L−d, the gap distance between the semiconductor wafer 10 and the upper surface 21 of the dielectric plate. As shown, for various values of product of Pd′, as the gap-distance d′ is reduced (assuming the pressure is constant) the breakdown voltage becomes lower. Then the curve reaches a minimum and rises steeply again as the gap-distance d′ is further reduced. In one embodiment, the gap distance d′ is determined by the proximity pin heights on the dielectric plate. In one example, for a polyimide chuck with proximity pins in 100 μm height, the observed breakdown voltage is shown by an open circle 201 right on the standard Paschen breakdown curve. In another example, for a polyimide chuck with proximity pins in 63 μm height, the observed breakdown voltage is shown by another open circle 203 which is also located on the Paschen curve but with lower value of breakdown voltage.

Referring to FIG. 2, due to the much smaller operating pressure and gap-distance, some conventional chucks are also indicated by several circles on the left side of the figure. For example, for an etch chuck with helium in the chamber as indicated by circle 211, the pressure usually is only 15 Torr and the gap-distance is about 30 μm or less. For an ESC robot blade in air with atmospheric pressure as indicated by circle 213, the wafer-to-chuck gap-distance is only about 1 μm or less. In another example, a PVD chuck with argon as indicated by circle 215, the argon pressure is about 4 Torr or less and the gap-distance also is very small, e.g., 4 μm or less. According to certain embodiments, the present invention provides methods that include operating the electrostatic chuck with desired chucking voltage above the Paschen curve. For example, the two dots 221 and 223 respectively indicate a desired voltage to be applied to the electrode of a polyimide chuck with 100 μm and 63 μm proximity pins for proper chucking a wafer thereon.

As shown in FIG. 1B, as the chucking voltage Vₑ applied to the two electrodes 30 increases, the voltage potential difference between the electrode and wafer is beyond a voltage threshold Vₜₕ which has a predetermined magnitude that is higher than the air breakdown voltage (i.e., Paschen curve limit) but still lower than a dielectric strength of the dielectric plate above the electrodes. To some extent, the magnitude of the Vₜₕ may depend on the proximity pin height for a particular chuck and actual pressure in the wafer-to-chuck gap during particular wafer processing. However, one of skill in the art will recognize relevant variations, alternatives, and modifications. In the case of Vₑ>Vₜₕ, air breakdown occurs as long as the wafer-to-chuck gap-distance is below a certain level and the surface of dielectric plate can build up substantial static charges σₛ thereon due to charge transfer associated with the air breakdown. As shown in FIG. 1A, before the air breakdown, the surface charges 121 is positive due to a positive voltage polarity and just a small amount due to the high dielectric constant and high resistivity of the dielectric plate. The air breakdown causes shorting between the surface 11 and the surface 21 so that charges 111 flow to the surface 21, resulting in a build-up of net charges there, i.e., the charges 125 shown in FIG. 1B opposing to the Electrode A. Similarly, charges 126 are built up on the other portion of the surface 21 opposing to the Electrode B.

In one embodiment, as Vₑ further increases, the amount of charges 125 and 126 may increase unless the voltage Vₑ is still much lower than the dielectric strength of the dielectric plate to cause its dielectric breakdown. In another embodiment, the voltage Vₑ on the electrodes is quickly reduced to approximate zero (i.e., Vₑ˜0) as part of the chucking sequence after being maintained at a level above the voltage threshold Vₜₕ for a time period. The wafer is still at potential zero by grounding (V_{w}=0). As the voltage Vₑ drops to zero, static charges will move to the lower surface of the wafer while the charges on the upper surface of dielectric plate will mostly be retained due to the high resistivity of the dielectric plate. Therefore, the electric field induced by these static charges between the wafer and the dielectric plate becomes the source of the attractive chucking force. As shown in FIG. 1C, the charges 125′ and 126′ on the surface 21 respectively are substantially the same as the charges 125 and 126 built during air breakdown charge transfer (FIG. 1B). These charges 125′ and 126′ in turn induce charges 111′ and 112′ with opposite signs on the corresponding regions of the lower surface 11 of the semiconductor wafer. Embodiments of the invention lead to the chucking pressure at this stage of process in the following form,

$$P = - \frac{1}{2 {ɛ}_{0}} {( \frac{{σ}_{s} d}{d + κ ( L - d )} )}^{2} , \qquad ( Eq . 8 )$$

where σₛ denotes as the static charges retained on the surface of the dielectric plate. Since the charges σₛ on the surface of dielectric plate built up through air breakdown charge transfer can be much larger in quantity than those simply caused by charge motion within the dielectric plate due to non-ideal insulation. The resulting chuck pressure P can be sufficiently high to hold the semiconductor wafer even with the large gap-distance and high pressure.

Compared to a conventional case with the chuck voltage as high as the Paschen observed breakdown voltage V_{B} and a same gap-distance (L−d), the chuck pressure reaches a maximum as in the following form,

$$P = - \frac{{ɛ}_{0}}{2} {( \frac{{V}_{B}}{L - d} )}^{2} . \qquad ( Eq . 9 )$$

It is interesting to compare the results of Eq. 8 and Eq. 9. As an example, the pressure associated with a voltage Vₑ=V_{B}=800 V with the wafer at potential zero, for a typical values of d=50 microns, L=150 microns, κ=2.1, then the chucking pressure with no surface charge is obtained using Eq. 9, i.e., P=180 Pa. But when the charges are brought to the surface of the dielectric plate by first turning on electrostatic chucking power with Vₑ greater than air breakdown threshold before (or after) the wafer touches the proximity pins for a short time period then turning off the power to bring Vₑ back to zero (Vₑ=V_{w}=0), these surface charges, assuming they correspond to 800 V potential difference, should provide 280 Pa of chucking pressure based on Eq. 8.

In an embodiment, by using a high resistivity dielectric for the electrostatic chuck, the charges built up on the surface of the dielectric plate remains relatively immobile for a time period during which the wafer can be chucked on for any relevant processing including but not limiting to lithography, ion implantation, plasma etching, film deposition, and thermal treatment. For example, the dielectric plate of the electrostatic chuck can be made of Kapton polyimide. In another example, it can be made of other high strength dielectric like sapphire. The time period for retaining those charges can be reasonably achieved to be greater than typical wafer process times. For example, the time period is at least 1 to 2 minutes. In another embodiment, the amount of charges may depend on how many charges are transferred, and on the uniformity of the breakdown across the wafer-to-chuck gap. Of course, there can be many alternatives, variations, and modifications.

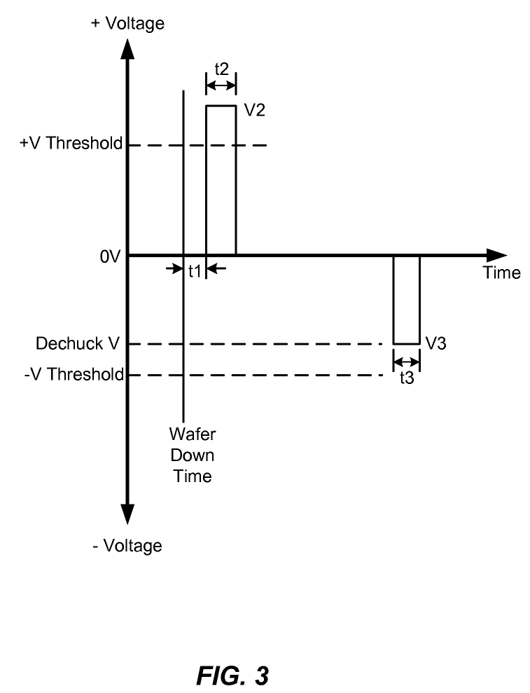

FIG. 3 shows an exemplary chucking and dechucking sequence according to an embodiment of the present invention. This diagram is merely an example, which should not unduly limit the scope of the claims herein. One of ordinary skill in the art would recognize many alternatives, variations, and modifications. As shown, the chucking or dechucking voltage applied to the electrodes is plotted as a function of time. The vertical axis represents the applied voltage Vₑ. 0 V at the middle represent a potential state of the electrode referenced to the wafer potential which is typically grounded with V_{w}=0. The positive or negative sign refers to the two possible voltage polarities, which only bears relative meaning but no absolute effect to the chucking sequence. Inherently, if a bipolar electrostatic chuck is used, FIG. 3 refers to a voltage applied to any one electrode which may have the same or different magnitude of a voltage applied to another electrode but definitely is in an opposite polarity. But it would not affect the results described in FIG. 3 and subsequent specification below. The horizontal axis just represents the time. For example, a Wafer-Down time is marked representing a wafer is loaded on the chuck.

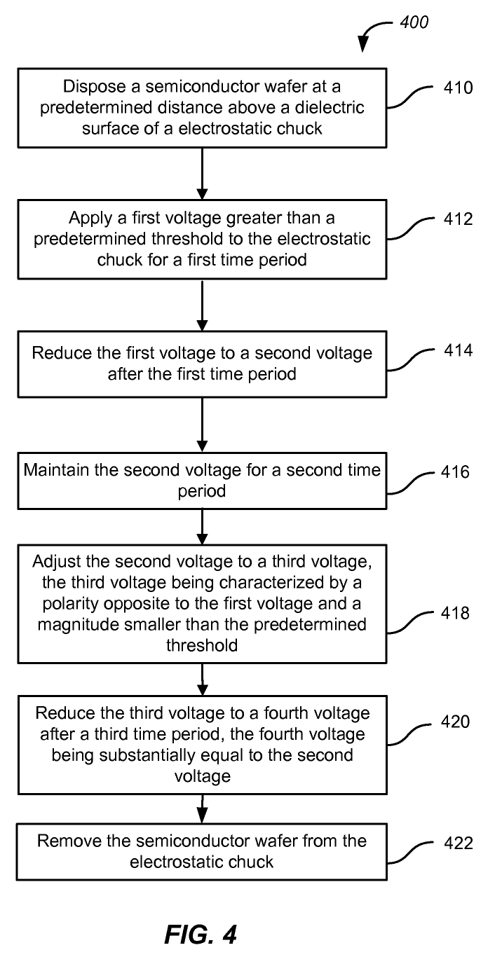

In order to illustrate one of the novel features of the chucking/dechucking sequence, FIG. 3 may be viewed in conjunction with FIG. 4 which is an exemplary flowchart showing a method for clamping and declamping a semiconductor wafer on an electrostatic chuck in ambient air according to an embodiment of the present invention. The flowchart is merely an example for performing the wafer chucking/dechucking processes, which should not unduly limit the scope of the claims herein. As shown the method 400 includes a process of disposing a semiconductor wafer at a predetermined distance above a dielectric surface of a electrostatic chuck (Process 410). This process can be referred in FIG. 3 as to start the wafer chucking process by first lowering the wafer onto the chuck. In particular, a semiconductor wafer in a track lithography tool can be loaded with a transfer robot at a predetermined distance above the surface of a dielectric plate of the electrostatic chuck at a Wafer-Down time. For example, the semiconductor wafer is the wafer 10 shown in FIGS. 1A-1C and the predetermined distance is a wafer-to-chuck gap distance determined substantially by a plurality of proximity pins on the surface of the dielectric plate. In another example, the dielectric plate is part of the bipolar electrostatic chuck 20 which embeds two electrodes 20.

The method 400 also includes a process of applying first voltage greater than a predetermined threshold to the electrostatic chuck for a first time period (Process 412). In one embodiment, the applying first voltage starts after a time t1 from the Wafer-Down time, as shown in FIG. 3. In another embodiment, the applying first voltage starts before the Wafer-Down time. In other words, t1 may have a relatively negative value if the Wafer-Down time is the zero point of time. In particular the first voltage applied in the Process 412 has a magnitude V2 greater than a voltage threshold and lasts for a time period t2. In one embodiment, a DC power supply configured to change voltage magnitude and switch voltage polarity is used to provide the first voltage such that the first voltage jumps from zero to the magnitude V2 with a time constant substantially shorter than t2. The voltage threshold is a predetermined value depending on the gap-distance and the pressure in the gap when the wafer is supported by the plurality of proximity pins on the surface of the dielectric plate. Of course, there can be other alternatives, variations, and modifications. For example, the magnitude V2 of the first voltage should be practically limited below the dielectric strength of the dielectric plate of the electrostatic chuck, depending on the material made thereof.

The method 400 further includes a process of reducing the first voltage to a second voltage after the first time period (Process 414). In one embodiment, the second voltage is substantially equal to a self bias potential of the first semiconductor wafer. In particular, the semiconductor wafer typically is grounded when bipolar electrostatic chuck is used. In this case, the second voltage is approximate zero, as shown in FIG. 3. For example, the DC power supply is configured to turn off power so that the first voltage quickly drops to zero (the second voltage). In another embodiment, the time constant for the power-off process is substantially shorter than t2. For example, FIG. 3 shows that the chucking process is simply represented by a square pulse having a pulse width t2 and pulse strength V2. In certain embodiments, if a monopolar chuck is used which necessarily has a plasma or a direct electrical contact to the wafer being at a certain non-zero self-bias potential in order to be properly chucked. Then the second voltage would be equal to the self-bias potential of the wafer.

The method 400 additionally includes a process of maintaining the second voltage for a second time period (Process 416). As described earlier part of this specification, the chucking voltage pulse applied in Process 414 create static charges on the dielectric surface by taking advantage of air breakdown charge transfer across the wafer and the dielectric plate. As the first voltage is brought down to approximate zero, the static charges contribute to an enhanced chucking force to hold the wafer onto the chuck. In one embodiment, the process 416 is to keep the wafer in a chucking state while one or more wafer treatment processes are performed. For example, these processes include but are not limited to lithography, ion implantation, plasma etching, film deposition, and thermal treatment. In one example, the second time period for performing these processes may be 1 or 2 minutes.

The method 400 further includes a process of adjusting the second voltage to a third voltage which is characterized by a polarity opposite to the first voltage and a magnitude smaller than the predetermined threshold (Process 418) and followed by a process of reducing the third voltage to a fourth voltage after a third time period (Process 420). The process 418 basically starts a dechucking sequence to reduce the electrostatic chucking force holding the semiconductor wafer so that the wafer can be removed from the chuck. In one embodiment, adjusting the second voltage to a third voltage for a third time period is to apply a dechucking voltage pulse characterized by an opposite polarity to the chucking pulse and a magnitude V3 as well as a pulse width t3. In particular, as shown in FIG. 3, the second voltage is essentially zero and the third voltage is a negative pulse compared to a positive pulse during chucking. In another embodiment, the magnitude V3 is associated with the quantity of static charges retained during and at the end of the Process 416, which in turn determines a residue potential difference between the surface of dielectric plate and the wafer.

In an specific embodiment, the magnitude V3 is selected such that the combined voltage potential difference, i.e., the third voltage plus the residue charge induced potential difference, would be higher than the voltage threshold (while with a negative sign). In other words, Paschen breakdown for the air in the gap can occur between the surface of dielectric plate and the lower surface of the wafer, effectively moving the residue charges to the wafer. For example, if the residue charges correspond to a potential −500 V, a maximum voltage for chucking is V2, then the dechucking voltage may be chosen to be −(500 V+(V2−Vₜₕ)). Of course, there can be other variations, alternatives, and modifications in detail selection of the dechucking voltage in response to the chucking voltage applied earlier and a desired amount of residual charges on the dielectric surface. According to an embodiment, the residual charges on the surface of the dielectric plate can be measured and real-time monitoring can be performed using a plurality of electrical (capacitance) sensors. These sensors can detect and provide information regarding whether the chucking is complete or dechucking sequence has properly released the wafer. In yet another specific embodiment, the dechucking pulse is also controlled by its pulse width, i.e., the third time period t3, so that most residue charges on the surface of the dielectric plate are substantially drained off or at least not many left there. In addition, after t3, the third voltage is brought down quickly to a fourth voltage so that the surface will not be re-charged with an opposite sign; and the fourth voltage essentially is approximate zero (with the DC power supply being turned off). Similar to the case of applying chucking voltage pulse, the DC power supply can be configured to apply dechucking voltage pulse or reduce it back to approximate zero with a time constant substantially shorter than the pulse width t3.

Finally, as the dechucking process is done after Process 420, the method 400 includes removing the semiconductor wafer from the electrostatic chuck (Process 422) followed by other processes including reloading a second wafer for essentially the same wafer treatment. In one embodiment, after going through the chucking/dechucking of each wafer on these bipolar chucks, the initial chucking voltage applied to any wafer loaded next is preferred to have a reversed polarity versus the applied chucking voltage for the last wafer. Because the dechucking sequence usually may not be able to completely drain off all static charges on the surface of the dielectric plate, the reversion of voltage polarity from one wafer to the next can eliminate long term drift in the chucking force due to buildup of the residue charges with one particular sign on the surface of the dielectric plate.

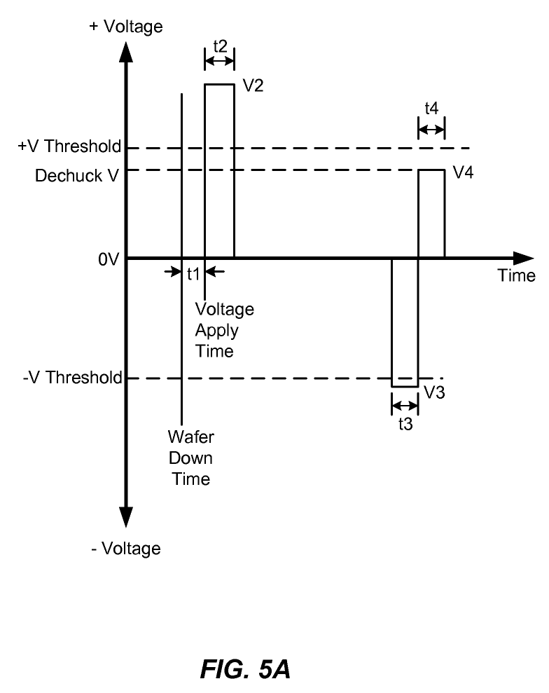

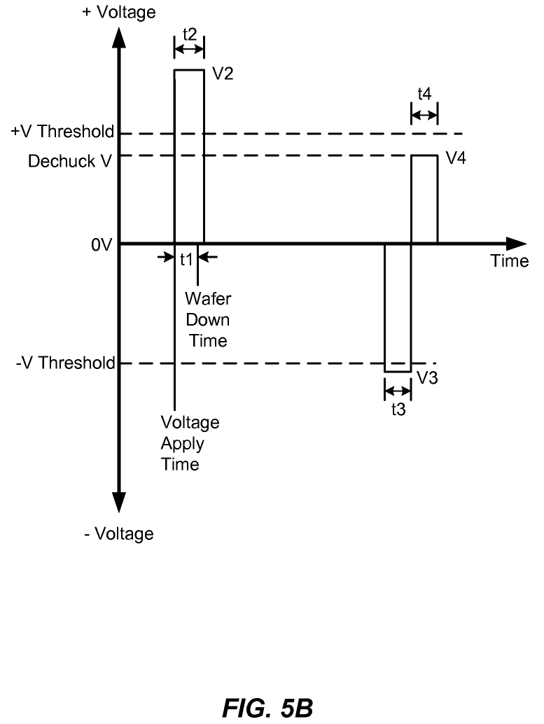

FIG. 5A shows an exemplary chucking and dechucking sequence according to an alternative embodiment of the present invention. FIG. 5B shows another exemplary chucking and dechucking sequence according to another embodiment of the present invention. These diagrams are merely examples, which should not unduly limit the scope of the claims herein. One of ordinary skill in the art would recognize many alternatives, variations, and modifications. As shown in FIG. 5A, the chucking or dechucking voltage applied to the electrodes is plotted against the time. In particular, the chucking sequence is the same as that shown in FIG. 3 but the dechucking sequence is different. In FIG. 5B, a dechucking pulse with an opposite polarity to the chucking voltage and a pulse height V3 greater than a predetermined voltage threshold is applied and thereafter followed by a forward pulse with again a reversed polarity and another pulse height V4 smaller than the predetermined voltage threshold with opposite sign. As shown in FIG. 5B, the chucking sequence is different from that in FIG. 5A in terms of the difference of the Voltage-Apply time, though the dechucking sequence may be the same. In particular, FIG. 5A shows that the chucking voltage up to the magnitude of V2 is applied at the Voltage-Apply Time, which is a time period of t1 after the Wafer-Down time. On the other hand, FIG. 5B shows that the chucking voltage V2 is applied at the Voltage-Apply time, which is at the time period of t1 before the Wafer-Down time. In one embodiment, the chucking sequence shown in FIG. 5B provides favorable advantages in terms of the quickness of holding the wafer and achieving thermal uniformity during the subsequent process over the chucking sequence shown in FIG. 5A. Further details can be found throughout this specification and more particular below.

In one embodiment, the dechucking pulse height V3 surpassing the predetermined voltage threshold for a time period t3 (dechucking pulse width) is to erase a memory of any surface charge leakage through the dielectric plate due to relatively lowered resistivity at elevated temperatures or simply non-uniformity of charge distribution after long processing time. With such a dechucking voltage pulse V3 applied for the time period t3, the charges remained on the dielectric surface are transferred in the opposite direction in an amount that is controlled by the threshold voltage only, not by any potential induced by pre-existing charges from leakage. Therefore, the thereafter followed forward pulse at time period t4, which essentially is similar to the single dechucking voltage pulse applied in case shown in FIG. 3, is determined by a known amount of more uniformly distributed surface charges. In one embodiment, the time constants associated with switching voltage pulse from zero to a magnitude of V3 or from a magnitude of V3 to another magnitude of V4 are substantially short compared to the time of charge leakage through the dielectric plate (which is essentially a RC time-constant for the dielectric plate material). In certain embodiments, the DC power supply is configured to switch the voltage pulse from zero to V3 or from V3 to V4 with the time constant much shorter than the time period t3 or t4. As shown, these voltage pulses are represented as a square wave pulse.

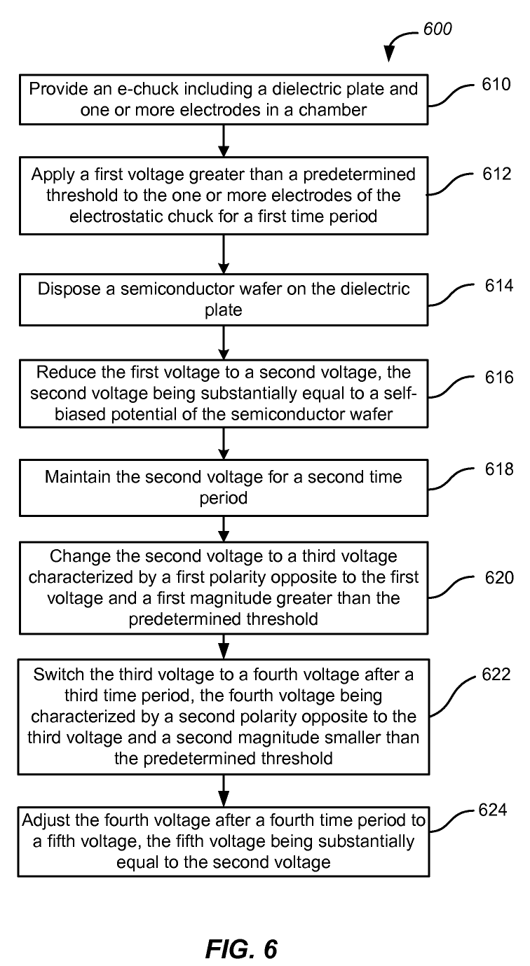

FIG. 6 is an exemplary flowchart showing a method for clamping and declamping a semiconductor wafer on an electrostatic chuck according to an alternative embodiment of the present invention. The flowchart is merely an example for performing the wafer chucking/dechucking processes, which should not unduly limit the scope of the claims herein. As shown, the method 600 includes providing an electrostatic chuck (e-chuck) in a chamber (Process 610). The e-chuck includes a dielectric plate and one or more electrodes. For example, the e-chuck is a bipolar electrostatic chuck with an Electrode A and an Electrode B embedded a thickness d below a surface of the dielectric plate. In one example, the e-chuck is the electrostatic chuck 20 shown in FIG. 1A. In another example, the e-chuck is also a bake plate located in a thermal processing chamber of a track lithography tool.

The method 600 also includes applying a chucking voltage greater than a predetermined voltage threshold to the one or more electrodes (Process 612) for a time period t2 and disposing a semiconductor wafer on the dielectric plate (Process 614). In one embodiment, the chucking voltage is supplied by a DC power supply coupled to the one or more electrodes. The DC power supply is controlled by a coupled controller which includes a computer-readable medium storing a plurality of instructions for controlling a data processor to adjust the power supply voltage. For example, some of the plurality of instructions to the data processor include applying the chucking voltage with controlled timing, voltage polarity, voltage magnitude, time constant for changing from one magnitude to another, and the like. In one example, the voltage polarity is positive for Electrode A but negative for Electrode B when a bipolar electrostatic chuck is used. In other example (when performing chucking a different wafer), the voltage polarity may be reversed. The predetermined voltage threshold is a function of a Paschen air breakdown voltage depending on the pressure P in the chamber in the vicinities of the chuck and wafer as well as a gap-distance d′ when the wafer is chucked on the electrostatic chuck. In particular, on the one hand the chucking voltage should be sufficiently higher than the predetermined voltage threshold to induce an electric breakdown in the air gap between the wafer and chuck. On the other hand the chucking voltage should be still substantially smaller than a dielectric constant of the dielectric plate so that there is no shorting between the surface of the dielectric plate and the one or more electrodes.

In another embodiment, the process 614 is a wafer loading process during which a transfer robot is used to handle the wafer and place it at various positions with predetermined distances above the dielectric plate. In certain embodiments, the dielectric plate of the e-chuck includes a plurality of proximity pins made of sapphire balls partially embedded in the upper surface of the dielectric plate. In one example, the process 614 includes placing the wafer into a final position so that at least some points of the lower surface of the wafer is supported by some of the plurality of proximity pins and rest area of the lower surface is separated by variable distances depending on extent of wafer warpage and variation in heights of the proximity pins. In the wafer loading process, the wafer-to-chuck gap distances at various positions, including the final position, can be monitored in real time and signals of the gap distances are sent to the same data processor used for controlling the DC power supply.

In a specific embodiment, the method 600 including performing the process 612 at a certain time before or after the process 614. In one example, referring back to FIG. 5A, a Wafer-Down time is marked, representing that the wafer is in the final position described in last paragraph, when the wafer is in contact with the plurality of proximity pins. The chucking voltage V2 is applied at a time period t1 after the Wafer-Down time. Here the magnitude V2 is greater than the predetermined voltage threshold. In another example, referring back to FIG. 5B, the chucking voltage V2 is applied at a time period t1 before the wafer is in the final position at the Wafer-Down time. In particular, as the wafer is loaded by the transfer robot and the wafer to chuck gap distance is reduced, the gap distance is monitored so that application of the chucking voltage can be triggered, at a Voltage-Applying time, as long as the gap distance falls below a certain value, for example, about 3 mm. The wafer is then further lowered by the transfer robot after the Voltage-Apply time until the final position is reached by the Wafer-Down time. The chucking voltage according to a predetermined chucking sequence will be maintained at the magnitude V2 for at least a time period t2. The magnitude V2 can be selected to be sufficiently higher than the corresponding Paschen limit so that the air breakdown may occur before the wafer reaches its final position. Therefore, the air breakdown may occur before the Wafer-Down time, i.e., the end of time period t1 in FIG. 5B so that the wafer gets pulled down earlier by the induced static chucking force. In one embodiment, t2 is longer than t1 so that chucking voltage with a magnitude of V2 is on after t1. In another embodiment, t2 and t1 end at the same time. In other words, the chucking voltage is off just as the wafer is in final position. In this case, some processing time can be saved, or extra time is gained for thermal processing, which substantially enhances the uniformity of wafer heating. Once the wafer has reached its final position, a desired amount of charge may have been built up on the surface of dielectric plate over the time period t2.

After the time period t2, with the chuck voltage being maintained at the magnitude V2, the method 600 includes a process of reducing the voltage from V2 down to a second voltage level substantially equal to a self bias potential of the semiconductor wafer (Process 616). In one embodiment, an amount of static charges is transferred from the semiconductor wafer to the dielectric plate during the time period t2 as the applied chucking voltage achieves the magnitude V2. As the chucking voltage equals to the self bias potential of the semiconductor wafer, there is basically zero potential difference between the semiconductor wafer and the one or more electrodes, thereby effectively stopping further charge transfer. In a specific embodiment, the voltage is reduced by controlling the DC power supply under certain instructions preloaded in a data processor which is continuously updated with information associated with the self bias potential of the semiconductor wafer, an average gap distance, a capacitance between the wafer and the dielectric plate, and the like. Depending on the structural design the electrostatic chuck and the physical and electronic environment around the wafer, the self bias potential of the semiconductor wafer can be zero or a non-zero value. In another specific embodiment, the operation of the process 616 is associated with a time constant substantially smaller than the time period t2, so that a substantial portion of static charges can be retained on the surface of the dielectric plate. As shown in FIG. 3, FIG. 5A, or FIG. 5B, the chucking voltage is substantially a square pulse. Of course, there can be many variations, alternatives, and modifications.

Followed by the process 616, the static charges retained on the surface of dielectric plate can induce charges with opposite signs on an opposing region of the lower surface of the wafer, creating a static electric field that results in an enhanced chucking force sufficiently large to hold the wafer on the e-chuck. The method 600 includes maintaining the second voltage level at the self bias potential of the semiconductor wafer for another time period (Process 618). In one example, the self bias potential of the semiconductor wafer is zero so that the data processor can send certain instructions to keep the DC power supply off. During the time period, the static charges can be substantially retained on the surface of the dielectric plate without leaking to/from the electrodes due to high resistivity of the dielectric plate. In the mean time, the wafer will be chucked to the dielectric plate by the electrostatic chucking force and desired wafer processing can be performed. This time period typically can be as long as the wafer processing is performed, for example, 1 or 2 minutes and longer. In one example, the e-chuck is also a bake plate so that the wafer now can be treated thermally at elevated temperatures in an ambient environment within the processing chamber. The relatively large gap and high pressure between the lower surface of the wafer and the surface of the bake plate (i.e., the dielectric plate of the e-chuck) allows annealing characterized by more uniformity and with better thermal conduction than in conventional thermal processes. In another example, a lithography, etch, or other suitable process can be performed.

After the desired wafer processing is finished, the method 600 further includes applying a dechucking voltage pulse to the one or more electrodes (Process 620) and thereafter applying a forward voltage pulse to the one or more electrodes (Process 622). Applying a dechucking voltage essentially starts a dechucking process that reduces the electrostatic chucking force imposed on the wafer so that the wafer can be removed. According to certain embodiments, the process 620 includes applying the dechucking voltage pulse V3 with a pulse width t3 and a polarity opposite to the chucking voltage. In one embodiment, the process 620 is performed by the data processor to execute certain preloaded instructions to cause the DC power supply to change the second voltage level to V3 within a time constant substantially shorter than the pulse width t3. The magnitude of V3 is selected to be higher than the predetermined voltage threshold to initiate an air breakdown charge transfer between the lower surface of the wafer and the upper surface of the dielectric plate in a reverse direction compared to the earlier chucking process. This reverse charge transfer is able to at least partially cancel the retained static charges on the dielectric plate and also helps to remove a memory of any surface charge leakage through the dielectric plate due to relatively lowered resistivity at elevated temperatures or simply non-uniformity of charge distribution after long series of chucking/dechucking cycles. In one embodiment, the pulse width t3 and pulse height V3 can be adjusted by the data processor under certain pre-stored instructions to the DC power supply and based on amount of charges continuously sensed by a plurality of electric (capacitance) sensors.

After the time period of t3 associated with the pulse width of the dechucking voltage pulse, the remaining amount of charge on the surface of dielectric plate influences a capacitance value which is associated with the wafer-to-chuck gap distance. The capacitance value can be monitored by a plurality of capacitance sensors and be continuously sent to the data processor, which in turn determines how the subsequent forward pulse should be applied in Process 622. The forward pulse is characterized by a reverse polarity (compared to the dechucking pulse applied right before) and a pulse height V4 for a time period of t4 (i.e., the pulse width of the forward pulse). In one embodiment, the process 622 is performed by the data processor to execute certain preloaded instructions to cause the DC power supply to change the voltage from a magnitude V3 to another magnitude V4 with a reverse polarity within a time constant substantially shorter than the time period t3 or the time period t4. In another embodiment, the pulse height V4 of the forward pulse is adjusted based on the amount of remaining charges after the Process 620. In particular, the magnitude of V4 is selected so that a combined potential difference between the wafer and the e-chuck, including the voltage V4 plus the remaining-charge-induced potential difference, becomes just high enough to initiate another air breakdown charge transfer across the wafer-to-chuck gap during the time period t4. This air breakdown charge transfer occurs in a reverse direction compared to that induced by the dechucking voltage pulse during the time period t3, thereby helping draining off the remaining static charges on the surface of the dielectric plate.

Furthermore, the method 600 includes a process of adjust the voltage after the time period t4 from the magnitude V4 to a level substantially equal to a self bias potential of the semiconductor wafer (Process 624). In one embodiment, the self bias potential at this time is approximate zero and the voltage essentially is reduced to zero by turning off the DC power supply within a time constant substantially shorter than the forward voltage pulse width t4. In another embodiment, the process 624 is performed by monitoring the static charges on the surface of the dielectric plate by the plurality of capacitance sensors. Essentially, the pulse width t4 of the forward voltage pulse can be adjusted to control the air breakdown charge transfer during the time period t4 based on the remaining charge amount monitored by the capacitance sensors. In certain embodiments, both the dechucking voltage pulse and subsequent forward voltage pulse contribute to how the remaining charges on the dielectric plate are effectively drained off. In particular, combined input information associated with the charge amount, wafer-to-chuck gap-distance, air pressure, wafer warpage, and proximity pin height variations effectively determine how the DC power supply is controlled to generate output parameters for the dechucking/forward voltage pulses Though the charges may not likely or necessarily be completely removed due to non-uniformity or leakage from imperfect insulation, the chucking force between the wafer and the e-chuck is substantially reduced so that the wafer can be removed from the e-chuck.

Of course, the wafer chucking/dechucking methods according to embodiments of the present invention can be applied repeatedly in mass production. Certain embodiments of the invention includes to apply the initial chucking voltage to chuck the next wafer with a reversed polarity to that for chucking the last wafer. Advantages of this chucking polarity reversion lie in an effective elimination of long term drift in the chucking force due to buildup of the residue charges with one particular sign on the surface of the dielectric plate. Of course, other charge clean-up procedures can be performed as one of ordinary skilled would recognize many variations, alternative, and modifications.

As discussed above, one or ordinary skill in the art may recognize that the particular naming of the wafer, chuck, chamber, tool, proximity pin, power supply, sensor, data processor, and other aspects are not mandatory or significant. For example, the wafer may be a semiconductor wafer as mentioned in above specification for most typical applications. It also can be a metal wafer such as those used for making magnetic heads or a conductive substrate used for flat panel display. The size of the wafer, correspondingly the size of the e-chuck can vary, such as 100 mm, 125 mm, 200 mm, 300 mm, 400 mm or larger. The shape of the chuck or wafer is also not limited to circle or square or rectangular shape. The mechanisms that implement the invention or its features may have different names. One or ordinary skilled in the art may recognize that methods provided by the invention can be implemented as software, hardware, firmware or any combination of the three and is in no way limited to implementation in any specific programming language, or for any specific operating system or environment. Additionally, the apparatus or system that implements these electrostatic chucking sequences may include individual chambers, cluster tools, or in-line tools.

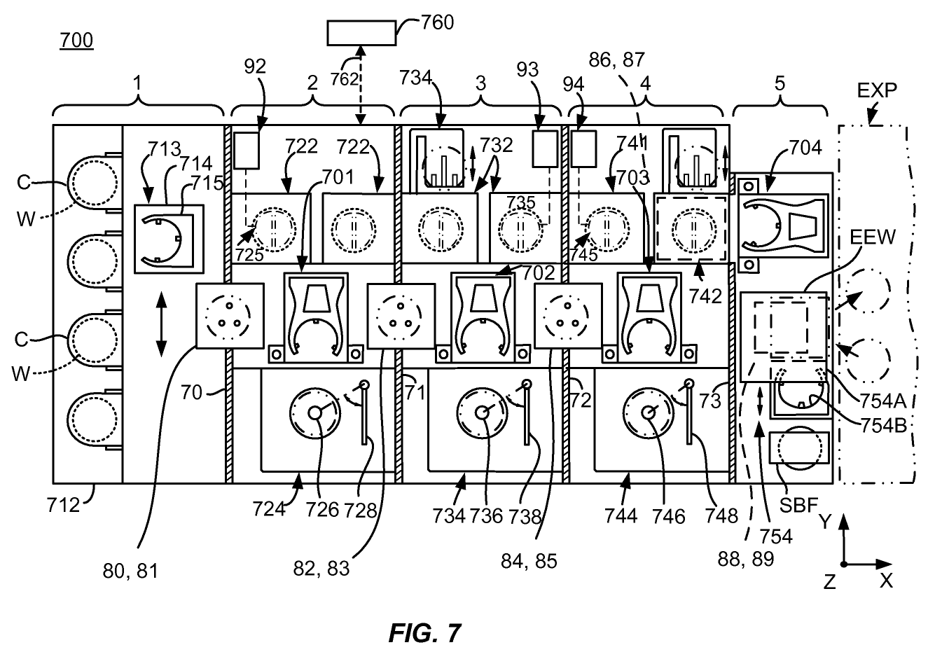

FIG. 7 is a plan view of a track lithography tool according to an embodiment of the present invention. In the embodiment illustrated in FIG. 7, the track lithography tool is coupled to an immersion scanner. An XYZ rectangular coordinate system in which an XY plane is defined as the horizontal plane and a Z axis is defined to extend in the vertical direction is additionally shown in FIG. 7 for purposes of clarifying the directional relationship therebetween.

In a particular embodiment, the track lithography tool is used to form, through use of a coating process, an anti-reflection (AR) and a photoresist film on substrates, for example, semiconductor wafers. The track lithography tool is also used to perform a development process on the substrates after they have been subjected to a pattern exposure process. Additional processes performed on the track lithography tool, which may be coupled to an immersion scanner, include PEB and the like. The substrates processed by the track lithography tool are not limited to semiconductor wafers, but may include glass substrates for a liquid crystal display device, and the like.

The track lithography tool 700 illustrated in FIG. 7 includes an factory interface block 1, a BARC (Bottom Anti-Reflection Coating) block 2, a resist coating block 3, a development processing block 4, and a scanner interface block 5. In the track lithography tool, the five processing blocks 1 to 5 are arranged in a side-by-side relation. An exposure unit (or stepper) EXP, which is an external apparatus separate from the track lithography tool is provided and coupled to the scanner interface block 5. Additionally, the track lithography tool and the exposure unit EXP are connected via LAN lines 762 to a host controller 760.

The factory interface block 1 is a processing block for transferring unprocessed substrates received from outside of the track lithography tool to the BARC block 2 and the resist coating block 3. The factory interface block 1 is also useful for transporting processed substrates received from the development processing block 4 to the outside of the track lithography tool. The factory interface block 1 includes a table 712 configured to receive a number of (in the illustrated embodiment, four) cassettes (or carriers) C, and a substrate transfer mechanism 713 for retrieving an unprocessed substrate W from each of the cassettes C and for storing a processed substrate W in each of the cassettes C. The substrate transfer mechanism 713 includes a movable base 714, which is movable in the Y direction (horizontally) along the table 712, and a robot arm 715 mounted on the movable base 714.

The robot arm 715 is configured to support a substrate W in a horizontal position during wafer transfer operations. Additionally, the robot arm 715 is capable of moving in the Z direction (vertically) in relation to the movable base 714, pivoting within a horizontal plane, and translating back and forth in the direction of the pivot radius. Thus, using the substrate transfer mechanism 713, the holding arm 715 is able to gain access to each of the cassettes C, retrieve an unprocessed substrate W out of each cassette C, and store a processed substrate W in each cassette C. The cassettes C may be one or several types including: an SMIF (standard mechanical interface) pod; an OC (open cassette), which exposes stored substrates W to the atmosphere; or a FOUP (front opening unified pod), which stores substrates W in an enclosed or sealed space.

The BARC block 2 is positioned adjacent to the factory interface block 1. Partition 70 may be used to provide an atmospheric seal between the factory interface block 1 and the BARC block 2. The partition 70 is provided with a pair of vertically arranged substrate rest parts 80 and 81 each used as a transfer position when transferring a substrate W between the factory interface block 1 and the BARC block 2.

Referring to FIG. 7 again, BARC block 2 includes a bottom coating processor 724 configured to coat the surface of a substrate W with the AR film, a pair of thermal processing towers 722 for performing one or more thermal processes that accompany the formation of the AR film, and the transport robot 701, which is used in transferring and receiving a substrate W to and from the bottom coating processor 724 and the pair of thermal processing towers or chambers 722. Each thermal processing chamber 722 houses a bake plate which is also an electrostatic chuck 725 for holding the substrate W during corresponding thermal processes. For example, the electrostatic chuck 725 is a chuck 20 described in FIG. 1. The electrostatic chucking is performed through applying a programmed voltage pulse supplied by a DC power supply 92 to generate clamping force. Additionally, each of the coating processing units or processors 724 includes a spin chuck 726 on which the substrate W is rotated in a substantially horizontal plane while the substrate W is held in a substantially horizontal position through suction. Each coating processing unit 724 also includes a coating nozzle 728 used to apply a coating solution for the AR film onto the substrate W clamped on the spin chuck 726, a spin motor (not shown) configured to rotatably drive the spin chuck 726, a cup (not shown) surrounding the substrate W held on the spin chuck 726, and the like.

The resist coating block 3 is a processing block for forming a resist film on the substrate W after formation of the AR film in the BARC block 2. In a particular embodiment, a chemically amplified resist is used as the photoresist. The resist coating block 3 includes a resist coating processor 734 used to form the resist film on top of the AR film, a pair of thermal processing towers 732 for performing one or more thermal processes accompanying the resist coating process, and the transport robot 702, which is used to transfer and receive a substrate W to and from the resist coating processor 734 and the pair of thermal processing towers or 732. Each of the coating processing units includes a spin chuck 736, a coating nozzle 738 for applying a resist coating to the substrate W, a spin motor (not shown), a cup (not shown), and the like.

The thermal processing towers 732 include a number of vertically stacked bake chambers and cool chambers. In a particular embodiment, the thermal processing tower closest to the factory interface block 1 includes bake chambers and the thermal processing tower farthest from the factory interface block 1 includes cool chambers. In the embodiment illustrated in FIG. 7, each of the thermal processing towels includes a vertically stacked bake plate and temporary substrate holder as well as a local transport mechanism 734 configured to move vertically and horizontally to transport a substrate W between the bake plate and the temporary substrate holder and may include an actively chilled transport arm. The bake plate is also configured to be an electrostatic chuck 735 powered by a DC power supply 93 for applying chucking voltage to hold the substrate W on the bake plate during corresponding baking processes. As the substrate W is clamped on the bake plate, it actually is supported by a plurality of proximity pins (not shown) with a gap between the bottom of substrate W and the top of the bake plate. For example, the electrostatic chuck 735 is a chuck 20 described in FIG. 1. The gap is substantially determined by the proximity pin heights or certain degrees of wafer warpage. In one embodiment, the chucking/dechucking of the substrate W on the bake plate with enhanced electrostatic chucking pressure can be performed using the method 400 or method 600 even for a gap distance as large as 100 μm and a pressure within the gap as high as 1 atm according to certain embodiments of the present invention. In another embodiment, during the chucking and dechucking procedures, the static charges on the bake plate that contribute the electrostatic chucking may be monitored by one or more electric capacitance sensors (not shown) preinstalled on the bake plate. Additionally, the transport robot 702 is identical in construction to the transport robot 701 in some embodiments. The transport robot 702 is able to independently access substrate rest parts 82 and 83, the thermal processing towers 732, the coating processing units provided in the resist coating processor 734, and the substrate rest parts 84 and 85.

The development processing block 4 is positioned between the resist coating block 3 and the scanner interface block 5. A partition 72 for sealing the development processing block from the atmosphere of the resist coating block 3 is provided. The development processing block 4 includes a development processor 744 for applying a developing solution to a substrate W after exposure in the scanner EXP, a pair of thermal processing towers 741 and 742, and transport robot 703. Each thermal processing chamber 741 and 742 houses a bake plate which is also an electrostatic chuck 745 for holding the substrate W during corresponding thermal processes. For example, the electrostatic chuck 745 is a chuck 20 described in FIG. 1. The electrostatic chuck 745 may be powered by a DC power supply 94 for applying chucking voltage to generate a clamping force. For example, the clamping and declamping of the substrate W on the bake plate can be performed through the method 400 or method 600 described in this specification. Each of the development processing units includes a spin chuck 746, a nozzle 748 for applying developer to a substrate W, a spin motor (not shown), a cup (not shown), and the like.

The interface block 5 is used to transfer a coated substrate W to the scanner EXP and to transfer an exposed substrate to the development processing block 5. The interface block 5 in this illustrated embodiment includes a transport mechanism 754 for transferring and receiving a substrate W to and from the exposure unit EXP, a pair of edge exposure units EEW for exposing the periphery of a coated substrate, and transport robot 704. Substrate rest parts 88 and 89 are provided along with the pair of edge exposure units EEW for transferring substrates to and from the scanner and the development processing unit 4.

The transport mechanism 754 includes a movable base 754A and a holding arm 754B mounted on the movable base 754A. The holding arm 754B is capable of moving vertically, pivoting, and moving back and forth in the direction of the pivot radius relative to the movable base 754A. The send buffer SBF is provided to temporarily store a substrate W prior to the exposure process if the exposure unit EXP is unable to accept the substrate W, and includes a cabinet capable of storing a plurality of substrates W in tiers.

Controller 760 is used to control all of the components and processes performed in the cluster tool, including generating a plurality of instructions for DC power supplies 92, 93, 94 (respectively) to adjust chucking or dechucking voltage pulses applied to the electrostatic chucks 725, 735, or 745 for clamping or declamping substrates on the corresponding bake plates. For example, the instructions include but not limiting to steps described in the method 400. In another example, the instructions may include but not limiting to steps described in the method 600. In yet another example, the controller 760 adjust its control signal by receiving continuous monitor signals about the static charges and gap-distance from one or more capacitance sensors disposed on the electrostatic chuck. The controller 760 is generally adapted to communicate with the scanner EXP, monitor and control aspects of the processes performed in the cluster tool, and is adapted to control all aspects of the complete substrate processing sequence. The controller 760, which is typically a microprocessor-based controller, is configured to receive inputs from a user and/or various sensors in one of the processing chambers and appropriately control the processing chamber components in accordance with the various inputs and software instructions retained in the controller's memory. The controller 760 generally contains memory and a CPU (not shown) which are utilized by the controller to retain various programs, process the programs, and execute the programs when necessary. The memory (not shown) is connected to the CPU, and may be one or more of a readily available memory, such as random access memory (RAM), read only memory (ROM), floppy disk, hard disk, or any other form of digital storage, local or remote. Software instructions and data can be coded and stored within the memory for instructing the CPU. The support circuits (not shown) are also connected to the CPU for supporting the processor in a conventional manner. The support circuits may include cache, power supplies, clock circuits, input/output circuitry, subsystems, and the like all well known in the art. A program (or computer instructions) readable by the controller 760 determines which tasks are performable in the processing chambers. Preferably, the program is software readable by the controller 760 and includes instructions to monitor and control the process based on defined rules and input data.

Additional description of a substrate processing apparatus in accordance with embodiments of the present invention is provided in U.S. Patent Application Publication No. 2006/0245855, entitled “Substrate Processing Apparatus,” the disclosure of which is hereby incorporated by reference in its entirety. Although embodiments of the present invention are described herein in the context of the track lithography tool illustrated in FIG. 7, other architectures for track lithography tools are included within the scope of embodiments of the present invention. For example, track lithography tools utilizing Cartesian architectures are suitable for use with embodiments as described throughout the present specification. In a particular embodiment, implementation is performed for an RF³i, available from Sokudo Co., Ltd., of Kyoto, Japan.

It is also understood that the examples and embodiments described herein are for illustrative purposes only and that various modifications or changes in light thereof will be suggested to persons skilled in the art and are to be included within the spirit and purview of this application and scope of the appended claims.

What is claimed is:

1. A method of clamping and declamping a semiconductor wafer on an electrostatic chuck in ambient air, the method comprising:
disposing a semiconductor wafer at a predetermined distance above a dielectric surface of the electrostatic chuck having one or more electrodes;
applying a first voltage to the one or more electrodes of the electrostatic chuck for a first time period, the first voltage being greater than a predetermined threshold;
reducing the first voltage to a second voltage after the first time period, the second voltage being substantially equal to a self bias potential of the semiconductor wafer;
maintaining the second voltage for a second time period;
adjusting the second voltage to a third voltage, the third voltage being characterized by a polarity opposite to that of the first voltage and a magnitude smaller than the predetermined threshold; and
reducing the third voltage to a fourth voltage after a third time period, the fourth voltage being substantially equal to the second voltage.

2. The method of claim 1 wherein disposing a semiconductor wafer at a predetermined distance above a dielectric surface of the electrostatic chuck comprises placing the semiconductor wafer in direct contact with a plurality of proximity pins, wherein the predetermined distance is determined by a gap between the semiconductor wafer and the dielectric surface and varies as a function of position as a result of wafer warpage.

3. The method of claim 2 wherein the gap between the semiconductor wafer and the dielectric surface comprises humidity-controlled air with a pressure of one atmosphere or higher in a vicinity of the semiconductor wafer and the electrostatic chuck.

4. The method of claim 1 wherein the predetermined threshold is associated with an air breakdown voltage that varies as a function of a product of a pressure and a distance between the semiconductor wafer and the dielectric surface.

5. The method of claim 1 wherein applying a first voltage to the one or more electrodes of the electrostatic chuck for a first time period starts at a fourth time period before disposing the semiconductor wafer at a predetermined distance above a dielectric surface of the electrostatic chuck, the fourth time period being shorter than or equal to the first time period.

6. The method of claim 5 wherein applying a first voltage to the one or more electrodes of the electrostatic chuck for a first time period starts at a time after disposing the semiconductor wafer at a predetermined distance above a dielectric surface of the electrostatic chuck.

7. The method of claim 1 wherein the electrostatic chuck comprises a bipolar electrostatic chuck including a first electrode and a second electrode, wherein one voltage applied to the first electrode has an opposite polarity of another voltage applied to the second electrode and the semiconductor wafer is grounded with the self-bias potential being zero.

8. The method of claim 1 wherein reducing the first voltage to the second voltage after the first time period is associated with a time constant substantially shorter than the first time period, thereby retaining an amount of static charge on the dielectric surface of the electrostatic chuck.

9. The method of claim 8 wherein the third voltage combined with a voltage potential resulted from the amount of static charges corresponds to a magnitude higher than the predetermined threshold, thereby causing the static charges on the dielectric surface to be substantially drained off.

10. The method of claim 9 wherein the static charges are associated with a capacitance corresponding to the predetermined distance monitored by one or more capacitance sensors.

11. The method of claim 1 wherein reducing the third voltage to a fourth voltage after a third time period comprises declamping the semiconductor wafer such that the semiconductor wafer is removable from the electrostatic chuck.

12. The method of claim 1 further comprising:
disposing a second semiconductor wafer on the electrostatic chuck after replacing the semiconductor wafer;
applying a fifth voltage to the one or more electrodes for chucking the second semiconductor wafer, the fifth voltage being characterized by a polarity opposite to the first voltage and a magnitude greater than the predetermined threshold.

13. A method of performing electrostatic chucking of a semiconductor wafer in ambient air, the method comprising:
providing an e-chuck in a chamber with ambient air, the e-chuck including one or more electrodes and a dielectric plate with a plurality of proximity pins;
applying a first voltage greater than a predetermined threshold to the one or more electrodes for a first time period;
disposing a semiconductor wafer on the dielectric plate such that a separation between the semiconductor wafer and the dielectric plate is reduced until at a time when the semiconductor wafer is in contact with the plurality of proximity pins;
reducing the first voltage to a second voltage after the first time period, the second voltage being substantially equal to a self-bias potential of the semiconductor wafer;
maintaining the second voltage for a second time period;
changing the second voltage to a third voltage, the third voltage being characterized by a first polarity opposite to that of the first voltage and a first magnitude greater than the predetermined threshold;
switching the third voltage after a third time period to a fourth voltage, the fourth voltage being characterized by a second polarity opposite to that of the third voltage and a second magnitude smaller than the predetermined threshold; and
adjusting the fourth voltage after a fourth time period to a fifth voltage, the fifth voltage being substantially equal to the second voltage.

14. The method of claim 13 wherein applying a first voltage greater than a predetermined voltage threshold to the one or more electrodes is performed as the separation between the semiconductor wafer and the dielectric plate is below a predetermined distance and before the time when the semiconductor wafer is in contact with the plurality of proximity pins.

15. The method of claim 13 wherein applying a first voltage greater than a predetermined voltage threshold to the one or more electrodes comprises setting the first voltage sufficiently higher than a Paschen air breakdown voltage constant for inducing a charge transfer across the separation between the semiconductor wafer and the dielectric plate, wherein the first voltage is still substantially smaller than a dielectric constant of the dielectric plate

16. The method of claim 15 wherein reducing the first voltage to a second voltage after the first time period is performed on or after the time when the semiconductor wafer is in contact with the plurality of proximity pins, thereby retaining a amount of static charges on the dielectric plate.

17. The method of claim 13 wherein changing the second voltage to a third voltage characterized by a first polarity opposite to that of the first voltage and a first magnitude greater than the predetermined voltage threshold comprises inducing a reverse Paschen air breakdown charge transfer across the separation between the semiconductor wafer and the dielectric plate.

18. The method of claim 13 wherein switching the third voltage after a third time period to a fourth voltage and adjusting the fourth voltage after a fourth time period to a fifth voltage comprise adjusting parameters including at least the first polarity, the first magnitude, the second polarity, the second magnitude, the third time period, the fourth time period, and the fifth voltage, thereby substantially draining off static charges on the dielectric plate.

19. A track lithography tool comprising:
a process chamber;
an electrostatic chuck disposed in the process chamber, the electrostatic chuck including a dielectric plate and one or more electrodes;
one or more capacitance sensors disposed on the dielectric plate;
a transfer robot configured to position a conductive wafer at a predetermined distance above the dielectric plate; and
a power supply configured to apply a voltage to the one or more electrodes, the power supply including a computer-readable medium storing a plurality of instructions for controlling a data processor to adjust the voltage, the plurality of instructions comprising:
instructions that cause the data processor to adjust the voltage to a first voltage for a first time period, the first voltage being greater than a predetermined threshold;
instructions that cause the data processor to reduce the first voltage to a second voltage after the first time period;
instructions that cause the data processor to maintain the second voltage for a second time period;
instructions that cause the data processor to adjust the second voltage to a third voltage, the third voltage being characterized by a polarity opposite to that of the first voltage and a magnitude smaller than the predetermined threshold; and
instructions that cause the data processor to reduce the third voltage to a fourth voltage after a third time period, the fourth voltage being substantially equal to the second voltage.

20. The track lithography tool of claim 19 wherein:
the process chamber comprises ambient air; and
the predetermined threshold is a function of an air breakdown voltage associated with a pressure of the ambient air and the predetermined distance between the conductive wafer and the dielectric plate.

21. The track lithography tool of claim 19 wherein:
the first voltage is determined to be substantially smaller than a dielectric strength of the dielectric plate;
the second voltage is determined to be substantially equal to a self bias potential of the semiconductor wafer so that an mount of static charges are retained on the dielectric plate; and
the third voltage is determined by the amount of static charges retained on the dielectric plate such that the combination of the third voltage and a potential due to the amount of static charges is larger than the first threshold.

22. The track lithography tool of claim 19 wherein the electrostatic chuck comprises a bipolar electrostatic chuck including a first electrode and a second electrode, wherein one voltage applied to the first electrode has an opposite polarity of another voltage applied to the second electrode.

23. A track lithography tool comprising:
a process chamber;
a bipolar electrostatic chuck disposed in the process chamber, the bipolar electrostatic chuck including two electrodes and a dielectric plate with a plurality of proximity pins;
one or more capacitance sensors disposed on the dielectric plate;
a transfer robot configured to dispose a conductive wafer on the dielectric plate such that a separation between the conductive wafer and the dielectric plate is reduced until the conductive wafer is in contact with the plurality of proximity pins;
a power supply configured to apply a voltage to each of the two electrodes; and
a controller coupled to the power supply, the controller including a computer-readable medium storing a plurality of instructions for controlling a data processor to adjust the voltage, the plurality of instructions comprising:
instructions that cause the data processor to adjust the voltage to a first voltage greater than a predetermined threshold for a first time period;
instructions that cause the data processor to reduce the first voltage to a second voltage after the first time period, the second voltage being substantially equal to a self-bias potential of the semiconductor wafer;
instructions that cause the data processor to maintain the second voltage for a second time period;
instructions that cause the data processor to adjust the second voltage to a third voltage, the third voltage being characterized by a first polarity opposite to that of the first voltage and a first magnitude greater than the predetermined threshold;
instructions that cause the data processor to adjust the third voltage after a third time period to a fourth voltage, the fourth voltage being characterized by a second polarity opposite to that of the third voltage and a second magnitude smaller than the predetermined threshold;
instructions that cause the data processor to adjust the fourth voltage after a fourth time period to a fifth voltage, the fifth voltage being substantially equal to the second voltage.

24. The track lithography tool of claim 23 wherein the predetermined threshold is a function of a Paschen air breakdown voltage that depends on a separation and an air pressure between the conductive wafer and the dielectric plate.

25. The track lithography tool of claim 23 wherein the first time period starts at a time before the conductive wafer is in contact with the plurality of proximity pins and ends at a time when or after the conductive wafer is in contact with the plurality of proximity pins.
